(19) United States
(12) Patent Application Publication
(10) Pub. No.: US 2025/0267839 A1
(43) Pub. Date: Aug. 21, 2025

(54) METHOD OF MANUFACTURING SEMICONDUCTOR DEVICE

(71) Applicant: Samsung Electronics Co., Ltd., Suwon-si (KR)

(72) Inventors: Hyunwoo BANG, Suwon-si (KR); Garam KIM, Suwon-si (KR); DOHYUNG KIM, Suwon-si (KR); JIWON YU, Suwon-si (KR); WOOMIN LEE, Suwon-si (KR)

(21) Appl. No.: 19/009,610

(22) Filed: Jan. 3, 2025

(30) Foreign Application Priority Data
Feb. 15, 2024 (KR) 10-2024-0021587

(51) Int. Cl. H10B 12/00

(52) U.S. Cl. CPC H10B 12/053

(57) ABSTRACT

A method of manufacturing a semiconductor device includes (a) forming a first trench, (b) adsorbing first particles and second particles along an inner wall of the first trench to form a first layer, (c) flowing an inert gas onto the first layer, (d) adsorbing third particles on the first layer to form a first compound, and (e) filling the first trench with the first compound to form a filler, wherein step (b) includes increasing a partial pressure of the first particles as a height from a lower surface of the first trench increases and making a partial pressure of the second particles substantially constant regardless of the distance from the lower surface of the first trench.

### CROSS-REFERENCE TO RELATED APPLICATIONS

This U.S. non-provisional patent application claims priority under 35 U.S.C. § 119 to Korean Patent Application No.10-2024-0021587 filed on Feb. 15, 2024, in the Korean Intellectual Property Office, the entire contents of which are hereby incorporated by reference.

### BACKGROUND OF THE INVENTION

The inventive concept relates to a method of manufacturing a semiconductor device, and more specifically, relates to a method of manufacturing a semiconductor device including a cell array region.

Semiconductor devices are widely used in the electronics industry due to their small size, multi-functional characteristics and/or low manufacturing costs. Semiconductor devices may be classified into semiconductor memory devices that store logical data, semiconductor logical devices that perform a logical data operation process, and hybrid semiconductor devices including memory elements and logical elements.

Recently, high speed and low consumption of electronic products require that semiconductor devices embedded in the electronic products should have high operating speed and/or lower operating voltage. For satisfying the above demands, semiconductor devices have been more highly integrated. The high integration of semiconductor devices may reduce the reliability of the semiconductor devices. However, the high reliability of semiconductor devices has been increasingly required with the advance in the electronics industry. Therefore, various research has been conducted for enhancing the reliability of semiconductor devices.

### SUMMARY

An object of the inventive concept is to provide to a method of manufacturing a semiconductor device with reduced process defects.

The problem to be solved by the inventive concept is not limited to the problems mentioned above, and other problems not mentioned may be clearly understood by those skilled in the art from the description below.

A method of manufacturing a semiconductor device according to some embodiments of the inventive concept may include (a) forming a first trench, (b) adsorbing first particles of a first gas comprising a first material and second particles of a second gas comprising a second material different from the first material along an inner wall of the first trench to form a first layer, (c) flowing an inert gas onto the first layer, (d) adsorbing third particles on the first layer to form a first compound, and (e) at least partially filling the first trench with the first compound to form a filler, wherein step (b) includes increasing an abundance of the first gas as a distance from a lower surface of the first trench increases, and making an abundance of the second gas substantially constant regardless of the distance from the lower surface of the first trench. The abundance of the first gas may comprise a partial pressure or a density of the first gas, and the abundance of the second gas may comprise a partial pressure or a density of the second gas.

A method of manufacturing a semiconductor device according to some embodiments of the inventive concept may include (a) forming a first trench on a base substrate, (b) adsorbing first particles of a first material and second particles of a second material different from the first material along an inner wall of the first trench to form a first layer, (c) flowing an inert gas onto the first layer, (d) flowing third particles on the first layer to form a first compound, and (e) at least partially filling the first trench with the first compound to form a filler, wherein step (d) includes reacting the first layer and the third particles, and a reaction rate between the first layer and the third particles decreases as a distance from a lower surface of the first trench increases.

A method of manufacturing a semiconductor device according to some embodiments of the inventive concept may include providing a substrate including cell regions, forming word lines on the cell region and bit lines electrically connected to the word lines, forming storage node contacts and fence patterns between the neighboring bit lines, and forming landing pads on the storage node contacts, wherein the forming of the landing pads includes (a) forming a landing trench on the storage node contacts, (b) adsorbing first particles of a first material and second particles of a second material different from the first material along an inner wall of the landing trench to form a first layer, (c) flowing an inert gas onto the first layer, (d) flowing third particles on the first layer to form a first compound, and (e) at least partially filling the first trench with the first compound to form a filler, step (d) includes reacting the first layer and the third particles, and a reaction rate between the first layer and the third particles decreases as a distance from a lower surface of the first trench increases.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

FIG. 1 is a flowchart showing a method of manufacturing a semiconductor device according to embodiments of the inventive concept.

FIGS. 2 to 6 are cross-sectional views showing a method of manufacturing a semiconductor device according to embodiments of the inventive concept.

FIG. 7 is a cross-sectional view illustrating a semiconductor device to which a semiconductor device manufacturing method according to embodiments of the inventive concept is applied.

FIG. 8 is a plan view illustrating a semiconductor device to which a semiconductor device manufacturing method according to embodiments of the inventive concept is applied.

FIGS. 9 to 11 are cross-sectional views illustrating a semiconductor device to which a semiconductor device manufacturing method according to embodiments of the inventive concept is applied.

FIGS. 12A, 12B, and 12C are plan views showing a method of manufacturing a semiconductor device according to embodiments of the inventive concept.

### DETAILED DESCRIPTION

Hereinafter, to explain the inventive concept in detail, embodiments according to the inventive concept will be described with reference to the accompanying drawings.

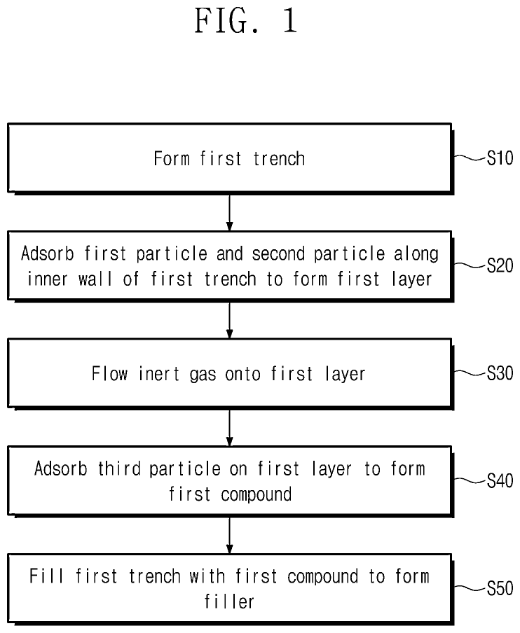

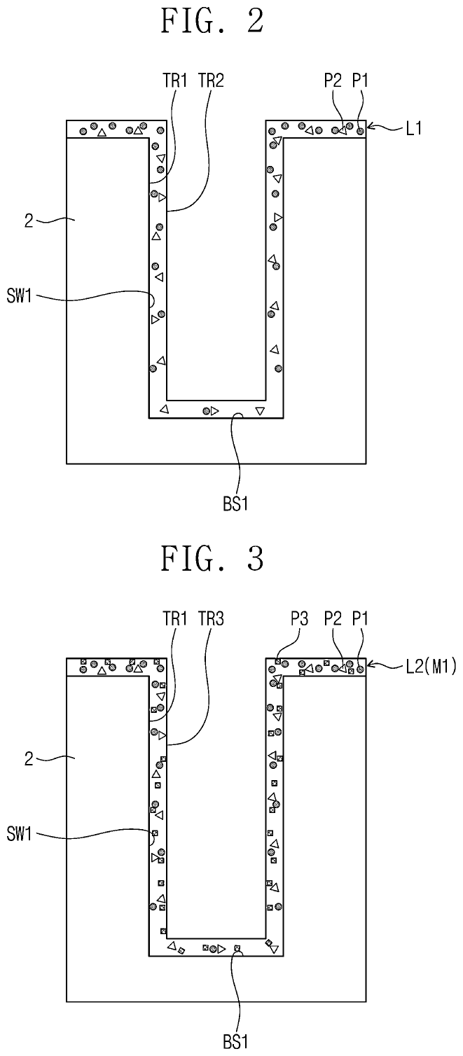

FIG. 1 is a flowchart showing a method of manufacturing a semiconductor device according to embodiments of the inventive concept. FIGS. 2 to 6 are cross-sectional views showing a method of manufacturing a semiconductor device according to embodiments of the inventive concept.

Referring to FIGS. 1 and 2, a base substrate 2 may be prepared. The base substrate 2 may be a semiconductor substrate, for example, a silicon substrate, a germanium substrate, or a silicon-germanium substrate. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases.

A first trench TR1 may be formed to penetrate a portion of a base substrate 2 in S10. For example, a portion of the base substrate 2 may be etched to form the first trench TR1. Forming the first trench TR1 may include forming a mask pattern (not shown) on the base substrate 2, and etching an upper portion of the base substrate 2 using the mask pattern as an etch mask. Although not shown, a plurality of first trenches TR1 may be formed. In this case, depths among the plurality of first trenches TR1 may be the same or different from each other. For example, lower surfaces of the first trenches TR1 may all be formed at the same level, or some lower surfaces may be formed at different levels from other lower surfaces. Here, “level” may describe a height measured relative to a lower layer of the base substrate 2, and may be described to describe a vertical distance from the lower layer of the base substrate 2.

First particles P1 and second particles P2 may be adsorbed along an inner wall SWI of the first trench TR1. For example, the first particles P1 and second particles P2 may be flowed in fluid (e.g., gas) form in order to be adsorbed along the inner wall of TR1. However, the form of fluid is not limited by the present disclosure. In some examples, the first and second particles may comprise two distinct materials. The first particles P1 and the second particles P2 may be adsorbed along the inner wall of the first trench TR1 to form a first layer L1 in S20. The first layer L1 May be formed along the sidewall SW1 of the first trench TR1, a lower surface BS1 of the first trench TR1, and an upper surface of the base substrate 2. The first layer L1 may be formed to form a second trench TR2. The first layer L1 may substantially conformally cover the inner wall of the first trench TR1. For example, the first layer L1 may be formed to have a uniform thickness. The first layer Ll may be formed through atomic layer deposition (ALD).

The first layer L1 may include the first material (e.g., the first particles P1) and the second material (e.g., the second particles P2). Forming the first layer L1 may be carried out at a temperature at which the first particles P1 and the second particles P2 do not react with each other. For example, the first layer L1 may be formed at a temperature between 500° C. and 650° C. The first particles P1 and the second particles P2 may be only adsorbed along the first trench TR1, and the first particles P1 and the second particles P2 may not react with each other.

An abundance of the first particles PI adsorbed may increase as a distance (e.g., a height) from the lower surface BS1 of the first trench TR1 increases. For example, a density (e.g., an area density) of the first particles P1 of the first layer L1 may increase as a distance (e.g., a height) from the lower surface BS1 of the first trench TR1 increases. A density of the second particles P2 of the first layer L1 may be substantially uniform regardless of the distance (e.g., height) from the lower surface BS1 of the first trench TR1.

In some examples, the abundance may also refer to the first gas, from which the first particles P1 are adsorbed, and/or to the second gas, from which the second particles P2 are adsorbed. For example, the abundance may refer to a partial pressure of the first and/or second gas.

Accordingly, in some examples, forming the first layer L1 may include increasing a partial pressure of the first gas, comprising the first particles P1, as the distance (e.g., height) from the lower surface BS1 of the first trench TR1 increases.

In some examples, forming the first layer L1 may include making the partial pressure of the second gas, comprising the second particles P2 substantially constant regardless of the distance from the lower surface BS1 of the first trench TR1.

Increasing the partial pressure of the first gas containing the first particles P1 with the distance (e.g., height) from the lower surface BS1 of the first trench TR1 may involve flowing the first particles P1 from a shower head (not shown) into the first trench TR1 in an unsaturated state. For example, the first gas may dilute as it spreads from the shower head (not shown), causing the partial pressure of the first gas to decrease with distance from the shower head.

In an example, the first particles P1 may not be flowed excessively, but may be flowed at a moderate and/or substantially constant flow rate or pressure until saturation. In this case, a relatively large amount of the first particles P1 may be adsorbed close to an upper portion of the first trench TR1 (e.g., saturating the surface of the upper portion of first trench TR1), which is closer to the showerhead (not shown), and a relatively small amount of first particles P1 may be adsorbed on a portion adjacent to the lower surface BS1 of the first trench TR1 (e.g., not saturating the lower surface BS1), which is farther from the shower head (not shown).

Keeping the partial pressure of the second gas containing the second particles P2 substantially constant regardless of the distance from the lower surface BS1 of the first trench TR1 may include flowing the second particles P2 from the showerhead (not shown) into the first trench TR1 in a sufficient amount to saturate the adsorbed first particles P1 within the first trench TR1.

For example, the second gas, comprising the second particles P2 may be flowed excessively and flowed at a flow rate or pressure sufficient to saturate the adsorbed first particles P1. In this case, the second particles P2 may be adsorbed substantially uniformly along the inner wall of the first trench TR1 regardless of the distance from the showerhead (not shown).

In one embodiment, forming the first layer L1 may include flowing the first gas, comprising the first particles P1 along the inner wall of the first trench TR1 in an amount that does not saturate the first particles P1, and then flowing a sufficient amount of the second gas, comprising the second particles P2, to saturate on the first particles P1 adsorbed along the inner wall of the first trench TR1. In this case, after the first particle P1 is adsorbed, the second particle P2 may be sequentially adsorbed.

In another embodiment, forming the first layer L1 may include mixing the first gas (comprising the first particles P1) in an amount that does not saturate the first particles P1 and the second gas (comprising the second particles P2) in a sufficient amount that the second particles P2 are saturated, and flowing them together along the inner wall of the first trench TR1. Forming the first layer L1 may include flowing an unsaturated amount of the first particles P1 and an amount of the second particles P2 sufficient to saturate the second particles P2 which are admixed together along the inner wall of the first trench. In this case, the first particles P1 and the second particles P2 may be adsorbed at the same time, since, for example, a mixed gas comprising both first particle P1 and second particle P2 are flowing.

In still another embodiment, forming the first layer L1 may include flowing a sufficient amount of the second gas (comprising second particles P2) to saturate the second particles P2 along the inner wall of the first trench TR1 and then flowing an amount of the first gas (comprising first particles P1) that do not saturate the first particles P1 onto the second particles P2 adsorbed along the inner wall of the first trench TR1. In this case, after the second particles P2 are adsorbed, the first particles P1 may be sequentially adsorbed.

The first particles P1 and second particles P2 may comprise different materials, which may be flowed in fluid form (e.g., in gas, suspension, and/or particulate form) in the first trench TR1 while being adsorbed. For example, the first particles P1 may include titanium. The first particles P1 may include or may be, for example, TiCl₄. In some examples, the second particles P2 may include silicon. The second particles P2 may include a silicon precursor. The second particles P2 may include or may be, for example, dichlorosilane (DCS) or SiH₄. A molecular weight of the first particles PI may be greater than that of the second particles P2. By lowering the partial pressure of the relatively heavy first particles P1, the Top/Bottom first particle P1 concentration is adjusted.

At least one inert gas may be flowed on the first layer L1 in S30. The inert gas may include argon or nitrogen, for example. Unadsorbed first particles P1 or second particles P2 may be removed by flowing the inert gas over the first layer L1.

Referring to FIGS. 1 and 3, a first compound M1 may be formed by adsorbing third particles P3 on the first layer L1 in S40. The first compound M1 may form the first compound layer L2. A third fluid (e.g., a third gas), comprising the third particles P3, may flow into the first trench TR1 where the first layer L1 is formed. The third particles P3 may be adsorbed onto the first layer L1, and the first layer L1 and the third particles P3 may react, thereby forming the first compound M1 and a first compound layer L2. As the first compound layer L2 is formed, a third trench TR3 may be formed.

Forming the first compound M1 may include reacting the first layer L1 and the third particles P3. A reaction rate between the first layer L1 and the third particles P3 may decrease as the distance increases from the lower surface BS1 of the first trench TR1. The reaction rate between the first layer L1 and the third particles P3 may be inversely proportional to the partial pressure of the first particles P1.

Because the partial pressure of the first particles P1 increases with distance (e.g., height) from the lower surface BS1 of the first trench TR1, the reaction rate between the first layer L1 and the third particles P3 may decrease with the distance (e.g., height) from the lower surface BS1 of the first trench TR1. When a molecular weight of the first particles P1 is greater than that of the second particles P2, the reaction rate may increase as the density of the first particles P1 with the larger molecular weight is decreased.

In an example, the third particles P3 may include NH₃. A molecular weight of the third particles P3 may be smaller than that of the first particles P1 and the second particles P2. The first compound M1 may include silicon-doped titanium nitride. The first compound M1 may include titanium silicon nitride. For example, the first compound M1 may have the chemical formula TiSixNy (where ‘x’ and ‘y’ are natural numbers equal to or greater than 0). In an example, a silicon concentration of the first compound M1 may increase as it approaches the lower surface BS1 of the first trench TR1.

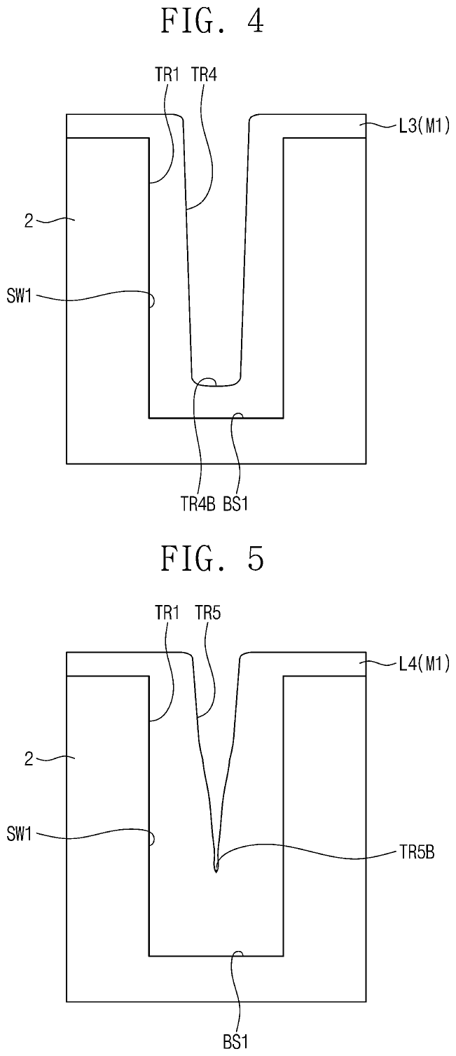

In some examples, atomic layer deposition (ALD) may continue in an iterative manner, as described below in the examples of FIGS. 4-7, particularly in FIG. 6, and described in step S50 of FIG. 1 above. For example, additional particles of the first material and second materials may be adsorbed into the trench; additional third particles may be flowed onto the adsorbed particles; the inert gas may be flowed; and these steps may be repeated until a filler is formed based on the first compound M1, as described herein below.

Referring to FIGS. 1 and 4, the first particles P1, the second particles P2, and the third particles P3 may continuously react to form the first compound M1. The first compound M1 may continue to be formed to form a first intermediate compound layer L3. The first compound M1 may be filled from the layer surface BS1 of the first trench TR1 in a bottom-up manner to form the first intermediate compound layer L3. The first intermediate compound layer L3 may include substantially the same material as the first compound M1. A reaction rate at which the first intermediate compound layer L3 is formed may be greater in a region closer to the layer surface BS1 of the first trench TR1. Accordingly, the first intermediate compound layer L3 may be formed while the first compound M1 is continuously formed from the lower surface BS1 of the first trench TR1. The first intermediate compound layer L3 may form a fourth trench TR4. As the first trench TR1 is not yet completely filled by the reaction of the first particles P1, the second particles P2, and the third particles P3, the fourth trench TR4 may be formed. A width of a lower surface TR4B of the fourth trench TR4 may be equal to or smaller than an exposed opening of the fourth trench TR4.

Referring to FIGS. 1 and 5, the first compound M1 may continue to be formed on the first intermediate compound layer L3. A second intermediate compound layer LA may be formed. The second intermediate compound layer L4 may be formed, and thus a fifth trench TR5 may be formed. A trench lowermost point TR5B may be defined at the lowermost point of an exposed portion of a fifth trench TR5. The trench lowermost point TR5B may be higher than a level of the lower surface TR4B of the fourth trench TR4.

A reaction rate at which the first compound M1 is formed may be higher in a region closer to the lower surface BS1 of the first trench TR1, for example, closer to the lower surface of the fifth trench TR5 and the trench lowermost point TR5B. The first compound M1 may fill the exposed opening of the fifth trench TR5 from a portion close to the lower surface of the fifth trench TR5.

Referring to FIGS. 1 and 6, the first trench TR1 may be completely or partially filled with the first compound M1 to form a filler F1 in S50. Forming the filler F1 may include completely or partially filling the first trench TR1 with the first compound M1 from the lower surface BS1 of the first trench TR1 without gaps.

Forming the filler F1 may include, for example, (i) adsorbing additional first particles P1 and additional second particles P2 into the first trench TR1, which is partially filled with the first compound M1, (ii) flowing the third particles P3 onto the adsorbed first particles P1 and/or second particles P2, (iii) flowing the inert gas, and (iv) repeating steps (i) to (iii) until the first trench TR1 is filled (e.g., completely or partially filled) with the first compound M1.

For example, the adsorbing of the first particles P1 and the second particles P2, the flowing of the third particles P3 onto the adsorbed first particles P1 and the second particles P2, and the flowing of the inert gas may be repeated until the first trench TR1 is filled with the first compound M1, for example to a target level.

As described above, when the molecular weight of the first particle P1 is greater than that of the second particle P2, and the partial pressure of the first gas, comprising the first particles P1, decreases as it approaches the lower surface BS1 of the first trench TR1, the reaction rate at which the first compound M1 is formed may increase as it approaches the lower surface BS1 of the first trench TR1.

Therefore, the rate at which the region close to the lower surface BS1 of the first trench TR1 is filled with the first compound M1 may be greater than the rate at which the region far from the lower surface BS1 of the first trench TR1 is filled with the first compound M1, and thus the first compound M1 may be sequentially filled from the lower surface BS1 of the first trench TR1 (e.g., in a bottom-up manner). In this case, the filler F1 formed by filling or partially filling the first trench TR1 with the first compound M1 may be void-free. Accordingly, reliability of the semiconductor device formed by the disclosed manufacturing method may be improved.

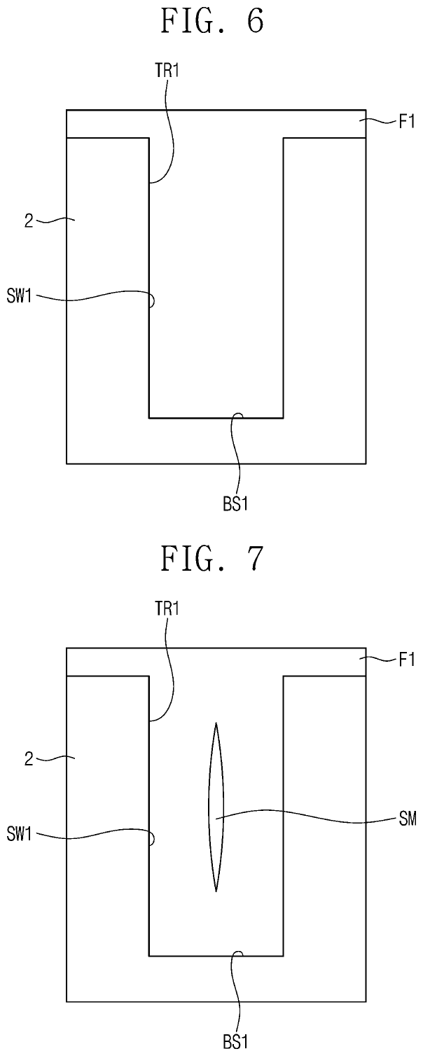

FIG. 7 is a cross-sectional view illustrating a semiconductor device to which a semiconductor device manufacturing method according to embodiments of the inventive concept is applied.

Referring to FIG. 7, a seam SM may be formed in the filler F1. For example, the seam SM may be formed in a center of the first trench TR1. An aspect ratio (height/critical dimension (CD)) of the first trench TR1 may be 3 or more.

When the aspect ratio (height/CD) of the first trench TR1 is less than 3, the seam SM may not be formed. For example, “step coverage” or “shadowing” may refer to blockage of evaporated material during deposition (e.g., by evaporation) by other features, such as protruding features. When the aspect ratio (height/CD) of the first trench TR1 is 3 or more and 10 or less, step coverage may be 100% or more and 140% or less.

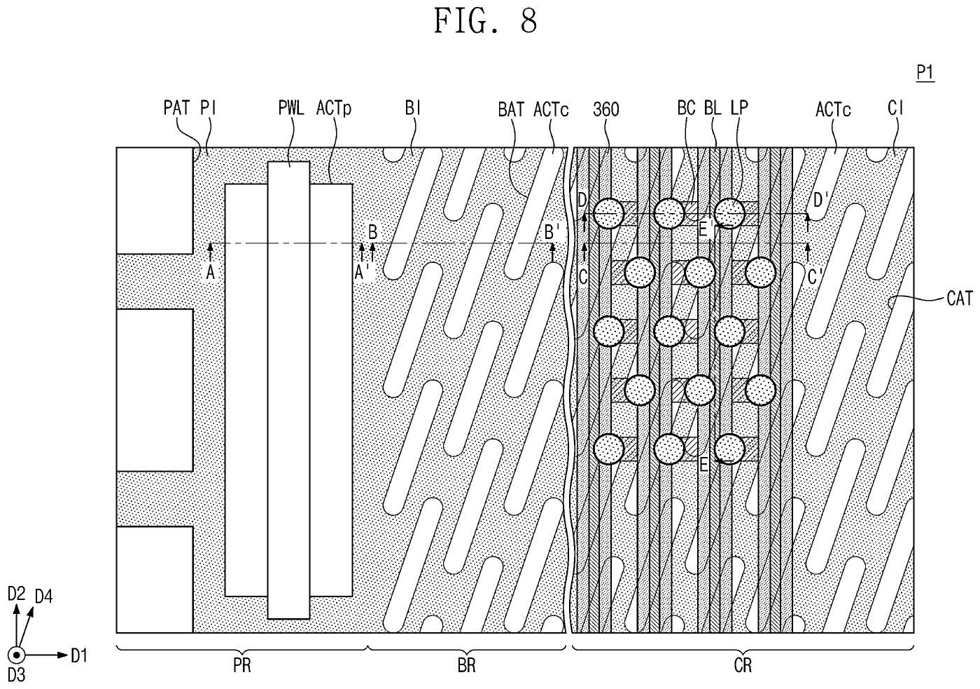

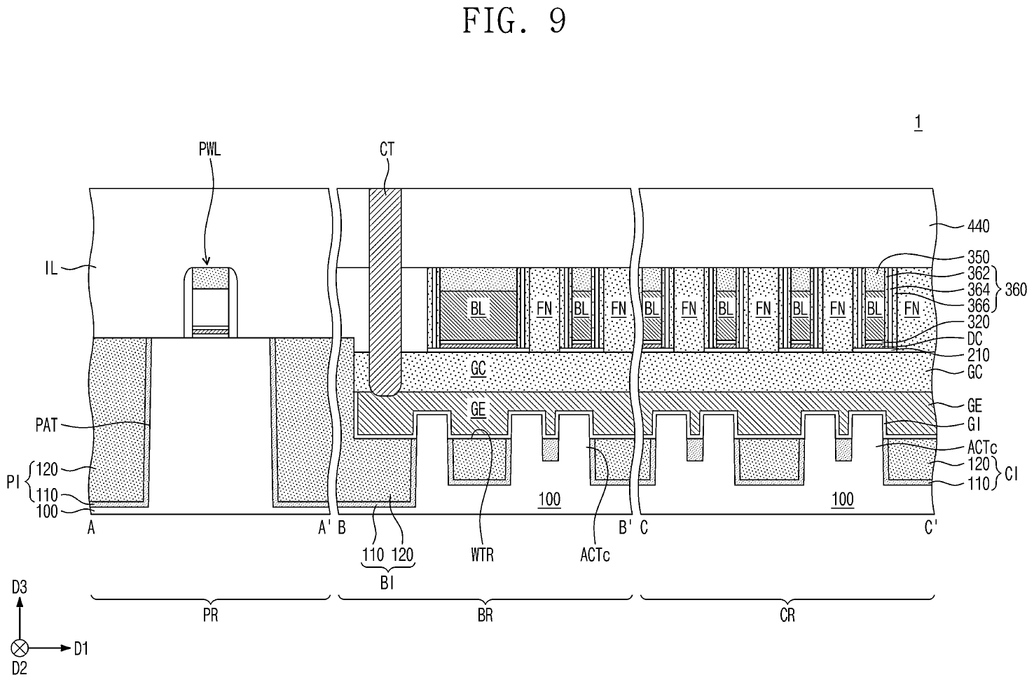

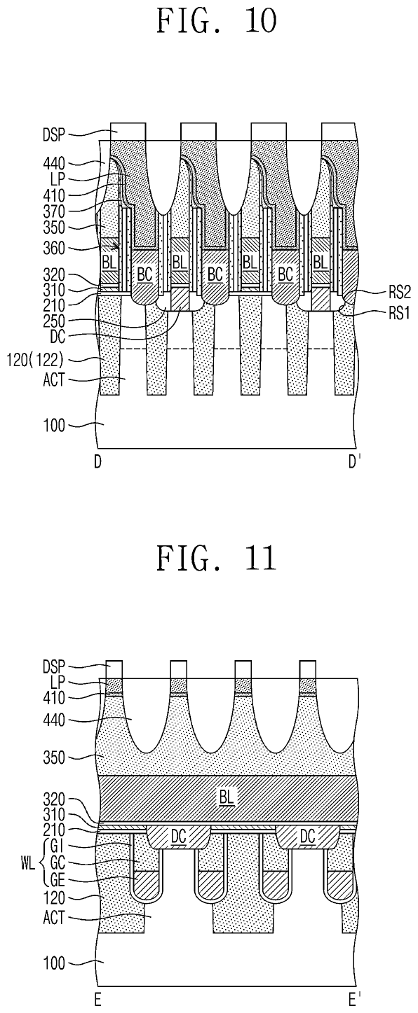

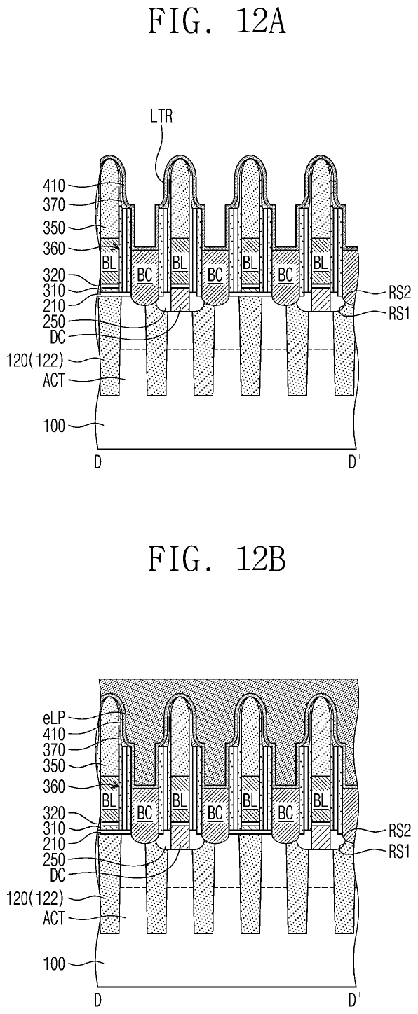

FIG. 8 is a plan view illustrating a semiconductor device to which a semiconductor device manufacturing method according to embodiments of the inventive concept is applied. FIGS. 9 to 11 are cross-sectional views illustrating a semiconductor device to which a semiconductor device manufacturing method according to embodiments of the inventive concept is applied. FIG. 9 is a cross-sectional view corresponding to lines A-A′, B-B′, and C-C′ of FIG. 8. FIG. 10 is a cross-sectional view corresponding to line D-D′ in FIG. 8. FIG. 11 is a cross-sectional view corresponding to line E-E′ in FIG. 8.

Referring to FIGS. 8, 9, 10, and 11, a semiconductor device 1 according to the inventive concept may include a substrate 100. As an example, the substrate 100 may include a cell region CR, a peripheral region PR, and a boundary region BR therebetween.

A device isolation pattern may be disposed on the substrate 100. As an example, the device isolation pattern may be disposed in a trench region provided on the substrate 100. The device isolation pattern may include a cell device isolation pattern CI on the cell region CR, a peripheral device isolation pattern PI on the peripheral region PR, and a boundary device isolation pattern BI on the boundary region BR. The cell device isolation pattern CI may be disposed in the cell trench region CAT that defines a cell activity patterns ACT on the cell region CR. The peripheral device isolation pattern PI may be disposed in the peripheral trench region PAT that defines a peripheral active patterns ACTp on the peripheral region PR. The boundary device isolation pattern BI May be disposed in the boundary trench region BAT between the cell active patterns ACTc and the peripheral active patterns ACTp on the boundary region BR. For example, the cell activity patterns ACTc on the boundary region BR may be dummy cell activity patterns, but are not limited thereto.

The cell active patterns ACTc and the peripheral active patterns ACTp may include a portion of the substrate 100 surrounded by the device isolation pattern. For convenience of explanation, unless otherwise stated, in this disclosure, the substrate 100 is defined to refer to a portion of the substrate 100 other than the above portion (e.g., the cell active patterns ACTc and the peripheral active patterns ACTp).

The cell active patterns ACTc may be spaced apart from each other in a first direction D1 and a second direction D2. The first direction D1 and the second direction D2 may be parallel to a lower surface of the substrate 100 and may intersect (e.g., orthogonal to) each other. The cell active patterns ACTc and the peripheral active patterns ACTp may protrude in a third direction D3 perpendicular to the lower surface of the substrate 100. Each of the cell activity patterns ACTc may have a shape extending elongatedly in a fourth direction D4.

Each of the device isolation patterns may include at least one of a first device isolation layer 110 and a second device isolation layer 120. For example, each of the first device isolation layer 110 and the second device isolation layer 120 may independently include silicon oxide or silicon nitride. For example, the first device isolation layer 110 and the second device isolation layer 120 may include different materials. For example, the second device isolation layer 120 May include a material with good gap-fill characteristics (e.g., Tonen SilaZene (TOSZ)). As an example, the first device isolation layer 110 may be a layer formed through a deposition process (e.g., an atomic layer deposition (ALD) process, etc.). For example, the first device isolation layer 110 and the second device isolation layer 120 may be in contact with each other without an interface. As another example, the first device isolation layer 110 and the second device isolation layer 120 may be distinguished from each other through an interface.

Components and structures of each device isolation pattern may be variously changed depending on widths of the cell trench region CAT, the peripheral trench region PAT, and the boundary trench region BAT, and thicknesses of the first and second device isolation layers 110 and 120.

Hereinafter, characteristics of the semiconductor device and other components in each of the cell region CR, the peripheral region PR, and boundary region BR will be described in detail.

Referring to FIGS. 9, 10, and 11, the peripheral region PR may include a peripheral active region ACTp on the substrate 100, a peripheral isolation layer PI defining the peripheral active region ACTp, a peripheral word line PWL on the peripheral active region ACTp, and an interlayer insulating layer IL on the peripheral word line PWL.

A level of an upper surface of the peripheral active region ACTp may be the same as a level of an upper surface of the peripheral device isolation layer PI. The peripheral active region ACTp may be defined by the peripheral device isolation layer PI.

The peripheral device isolation layer PI may be provided on the substrate 100. The peripheral device isolation layer PI may include a first device isolation layer 110 and a second device isolation layer 120. The first device isolation layer 110 and the second device isolation layer 120 may sequentially cover an inner wall of the peripheral trench region PAT. As an example, the first device isolation layer 110 may conformally cover the inner wall of the peripheral trench region PAT. The second device isolation layer 120 may fill the interior of the peripheral trench region PAT on the first device isolation layer 110.

The peripheral word line PWL may be placed on the peripheral active pattern ACTp. The peripheral active pattern ACTp may include a pair of impurity regions therein, and the peripheral word line PWL may cross the pair of impurity regions when viewed in a plan view. The peripheral word line PWL may include a plurality of patterns sequentially stacked on the peripheral active pattern ACTp, and peripheral spacers covering both sides thereof.

The interlayer insulating layer IL may cover the peripheral active pattern ACTp, the peripheral device isolation pattern PI, and the peripheral word line PWL on the peripheral region PR. The interlayer insulating layer IL may further cover the boundary device isolation pattern BI, which will be described later, on the boundary region BR.

The interlayer insulating layer IL may include an insulating material. As an example, the interlayer insulating layer IL may include at least one of silicon oxide, silicon nitride, TEOS, and a low dielectric material. For example, the interlayer insulating layer IL may be a single layer made of a single material or a composite layer containing two or more materials. Although not shown, the conductive structures may penetrate the interlayer insulating layer IL and may be electrically connected to the peripheral active pattern ACTp or the peripheral word line PWL, respectively.

The cell region CR may include a cell active region ACTc on the substrate 100, a cell device isolation layer CI defining the cell active region ACTc, a word line WL on the cell active region ACTc, a bit line contact DC, a first ohmic pattern 320 on the bit line contact DC, a bit line BL on the first ohmic pattern 320, bit line capping pattern 350 on the bit line BL, a bit line spacer 360 on a side surface of the bit line BL, and a filling pattern 440 on the bit line capping pattern 350.

A level of an upper surface of the cell active region ACTc may be lower than a level of an upper surface of the peripheral active region ACTp. The cell active region ACTc may be defined by the cell device isolation layer CI.

The cell isolation layer CI may be provided on the substrate 100. The cell isolation layer CI may include a first device isolation layer 110 and a second device isolation layer 120. The first device isolation layer 110 and the second device isolation layer 120 may sequentially cover the inner wall of the cell trench region CAT. As an example, the first device isolation layer 110 May conformally cover the inner wall of the cell trench region CAT. The second device isolation layer 120 may fill the interior of the cell trench region CAT on the first device isolation layer 110.

The word line WL may cross the cell active patterns ACTc. A plurality of word lines WL may be provided. The word lines WL may each extend in the first direction D1 and be spaced apart from each other in the second direction D2. The word line WL may be disposed in word line trenches WTR provided in the active patterns ACTc, the cell isolation pattern CI, and the boundary isolation pattern BI. For example, a pair of word lines WL adjacent to each other in the second direction D2 may cross one active pattern ACTc.

Each word line WL may include a gate electrode GE, a gate dielectric pattern GI, and a gate capping pattern GC. The gate electrode GE may penetrate the cell active patterns ACTc and the cell isolation pattern CI in the first direction D1. The gate dielectric pattern GI may be interposed between the gate electrode GE and the cell active patterns ACTc, and between the gate electrode GE and the cell isolation pattern CI. The gate capping pattern GC may cover an upper surface of the gate electrode GE. The gate electrode GE may include, for example, a conductive material. For example, the gate dielectric pattern GI may include at least one of silicon oxide and a high dielectric material. The gate capping pattern GC may include, for example, silicon nitride.

A buffer pattern 210 may be disposed on the substrate 100. The buffer pattern 210 may cover the cell active patterns ACTc, cell device isolation patterns CI, and word lines WL. As an example, the buffer pattern 210 may include at least one of silicon oxide, silicon nitride, silicon oxynitride, or a combination thereof. The buffer pattern 210 may be a single layer made of a single material or a composite layer containing two or more materials.

The bit line contact DC may be provided on each of the cell active patterns ACTc, or may be provided in the plural. The bit line contacts DC may be electrically connected to the cell active patterns ACTc, respectively. The bit line contacts DC may be spaced apart from each other in the first and second directions D1 and D2. The bit line contacts DC may be interposed between the cell active patterns ACTc and bit lines BL, which will be described later.

A first recess RS1 may be formed on the active patterns ACTc. A buried insulating pattern 250 may be provided in the first recess RS1. The buried insulating pattern 250 may cover at least a portion of a side surface of the bit line contact DC. The buried insulating pattern 250 may include at least one of silicon oxide, silicon nitride, or a combination thereof. The buried insulating pattern 250 may be a single layer made of a single material or a composite layer containing two or more materials.

The bit line BL may be provided on the bit line contact DC. The bit line BL may extend in the second direction D2. The bit line BL may be disposed on a row of bit line contacts DC arranged in the second direction D2. A plurality of bit lines BL may be provided. The bit lines BL may be spaced apart from each other in the first direction D1. The bit line BL may include a metal material. As an example, the bit line BL may include at least one of tungsten, rubidium, molybdenum, or titanium, or a combination thereof.

An intervening pattern 310 may be provided between the bit line BL and the buffer pattern 210. A plurality of intervening patterns 310 may be provided. An upper surface of the intervening pattern 310 may be disposed at substantially the same height as an upper surface of the bit line contact DC and may be coplanar. The intervening pattern 310 may include polysilicon doped with impurities.

The first ohmic pattern 320 may be interposed between the bit line BL and the bit line contact DC. The first ohmic pattern 320 may extend in the second direction D2 along the bit line BL. A plurality of first ohmic patterns 320 may be provided. The plurality of first ohmic patterns 320 may be spaced apart from each other in the first direction D1. The first ohmic pattern 320 may include metal silicide. A first barrier pattern (not shown) may be further interposed between the bit line BL and the bit line contact DC. The first barrier pattern may include a conductive metal nitride such as titanium nitride or tantalum nitride.

The bit line capping pattern 350 may be provided on an upper surface of the bit line BL. The bit line capping pattern 350 may extend in the second direction D2 on the upper surface of the bit line BL. A plurality of bit line capping patterns 350 may be provided. The plurality of bit line capping patterns 350 may be spaced apart from each other in the first direction D1. The bit line capping pattern 350 may vertically overlap the bit line BL. The bit line capping pattern 350 May be composed of a single layer or multiple layers.

The bit line spacers 360 may be provided on side surfaces of the bit line BL and side surfaces of the bit line capping pattern 350. The bit line spacer 360 may cover the side surface of the bit line BL and the side surface of the bit line capping pattern 350. The bit line spacer 360 May extend in the second direction D2 on the side surface of the bit line BL.

The bit line spacer 360 may include a plurality of spacers. As an example, the bit line spacer 360 may include a first spacer 362, a second spacer 364, and a third spacer 366. The first spacer 362 may be provided on the side surface of the bit line BL and the side surface of the bit line capping pattern 350. The third spacer 366 may be interposed between the first spacer 362 and a storage node contact BC, which will be described later. The second spacer 364 may be interposed between the first spacer 362 and the third spacer 366. As an example, the first to third spacers 362, 364, and 366 may each independently include at least one of silicon nitride, silicon oxide, silicon oxynitride, or a combination thereof. As another example, the second spacer 364 May include an air gap separating the first and third spacers 362 and 366.

A capping spacer 370 may be disposed on the bit line spacer 360. The capping spacer 370 may cover an upper side surface of the bit line spacer 360. The capping spacer 370 may include, for example, silicon nitride.

A second recess RS2 may be formed on the active pattern ACT. A storage node contact BC may be provided in the second recess RS2. The storage node contact BC may be provided between neighboring bit lines BL. As an example, the storage node contact BC may be interposed between neighboring bit line spacers 360. A plurality of storage node contacts BC may be provided. A fence patterns FN of the plurality of storage node contacts BC may be spaced apart from each other in the first and second directions D1 and D2. The storage node contacts BC May be spaced apart from each other in the second direction D2 by the fence patterns FN on the word lines WL. The fence pattern FN may be provided between neighboring bit lines BL. A plurality of fence patterns FN may be provided. The fence patterns FN may be spaced apart from each other in the first and second directions D1 and D2. The fence patterns FN adjacent to each other in the first direction D1 may be spaced apart from each other with the bit line BL interposed therebetween. The fence patterns FN adjacent to each other in the second direction D2 may be spaced apart from each other with the storage node contact BC. The fence patterns FN May include, for example, silicon nitride.

The storage node contact BC may include at least one of polysilicon or metal material undoped or doped with impurities, or a combination thereof.

A second barrier pattern 410 may conformally cover the bit line spacer 360, the fence pattern FN, and the storage node contact BC. The second barrier pattern 410 may include a metal nitride such as titanium nitride or tantalum nitride. A second ohmic pattern (not shown) may be further interposed between the second barrier pattern 410 and the storage node contact BC. The second ohmic pattern may include metal silicide.

A landing pad LP may be provided on the storage node contact BC. A plurality of landing pads LP may be provided.

The landing pad LP may be connected to a corresponding storage node contact BC. The landing pad LP may cover an upper surface of the bit line capping pattern 350. A lower region of the landing pad LP may vertically overlap the storage node contact BC. The landing pad LP May include a metal material such as tungsten, titanium, tantalum, etc.

The filling pattern 440 may conformally cover the bit line spacer 360, the fence pattern FN, and the storage node contact BC. As an example, the filling pattern 440 may include at least one of silicon nitride, silicon oxide, silicon oxynitride, or a combination thereof. As another example, the filling pattern 440 may include an empty space containing an air layer (i.e., an air gap).

A data storage pattern DSP may be provided on the landing pad LP. A plurality of data storage patterns DSP may be provided. The data storage pattern DSP may be, for example, a capacitor including a lower electrode, a dielectric layer, and an upper electrode. In this case, the semiconductor memory device according to the inventive concept may be a dynamic random access memory (DRAM). As another example, the data storage pattern DSP may include a magnetic tunnel junction pattern. In this case, the semiconductor memory device according to the inventive concept may be a magnetic random access memory (MRAM). As another example, the data storage pattern DSP may include a phase change material or a variable resistance material. In this case, the semiconductor memory device according to the inventive concept may be a phase-change random access memory (PRAM) or a resistive random access memory (ReRAM). However, this is only an example and the inventive concept is not limited thereto, and the data storage pattern DSP may include various structures and/or materials capable of storing data.

The boundary region BR may include a cell active region ACTc on the substrate 100, a boundary device isolation layer BI, a word line WL on the cell active region ACTc, a word line contact plug CT on the word line WL, and an interlayer insulating layer IL surrounding the word line contact plug CT.

The cell active region ACTc in the boundary region BR may be defined by the boundary device isolation layer BI. The cell active region ACTc in the boundary region BR may be, for example, a dummy active region.

The boundary device isolation layer BI may be provided on the substrate 100. The boundary device isolation layer BI may include a first device isolation layer 110 and a second device isolation layer 120. The first device isolation layer 110 and the second device isolation layer 120 may sequentially cover an inner wall of the boundary trench region BAT. As an example, the first device isolation layer 110 may conformally cover the inner wall of the boundary trench region BAT. The second device isolation layer 120 may fill the inside surface of the boundary trench region BAT on the first device isolation layer 110.

The word line WL may be provided on the cell active region ACTc of the boundary region BR. The word line WL of the boundary region BR may extend from the cell region CR. The word line WL may include a gate electrode GE, a gate dielectric pattern GI, and a gate capping pattern GC.

The word line contact plug CT may be provided on the gate electrode GE. The word line contact plug CT may be electrically connected to the word line WL. The word line contact plug CT may include a conductive material.

The gate capping pattern GC may surround the word line contact plug CT. The word line contact plug CT may penetrate the gate capping pattern GC. An interlayer insulating layer IL may be provided on the gate capping pattern GC. The interlayer insulating layer IL may surround the word line contact plug CT. The gate capping pattern GC and the boundary device isolation layer BI may form a stepped structure.

The semiconductor device manufacturing method described in FIGS. 1 to 6 may be applied to the semiconductor device P1 in FIGS. 8 to 11. Specifically, it may be applied when forming the landing pad LP, forming the word line WL, forming the word line contact plug CT, and forming the bit line contact DC. For example, the filler F1 may be the landing pad LP, the word line WL, the word line contact plug CT, and the bit line contact DC. Accordingly, the disclosed methods may reduce voids and improve semiconductor reliability for these or other components of the semiconductor device P1 in FIGS. 8 to 11.

Referring again to FIGS. 2 to 6 and 8, for example, when applied to form the word line contact plug CT, forming the first trench TR1 may include forming the first trench TR1 to penetrate a portion of substrate 100 including the cell region. In this case, the first trench TR1 may be formed to expose a portion of the word line WL, and the first compound M1 may fill the word line contact plug CT.

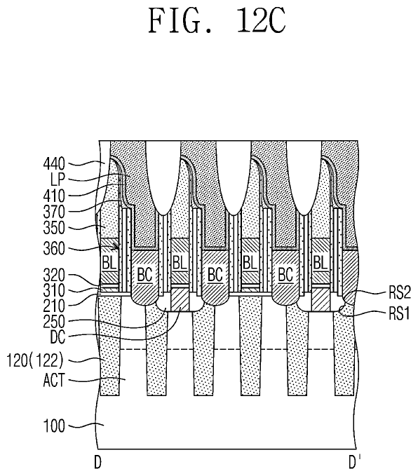

FIGS. 12A, 12B, and 12C are plan views showing a method of manufacturing a semiconductor device according to embodiments of the inventive concept.

Referring to FIGS. 11, 12A, 12B, and 12C, forming a landing pad LP through a method of manufacturing a semiconductor device according to embodiments of the inventive concept will be described.

Referring to FIGS. 2, 11, and 12A, a substrate 100 including a cell region CR may be provided. An active pattern ACT and a device isolation pattern 120 may be formed on the substrate 100. A word line WL and bit lines BL electrically connected to the word lines WL may be formed in the cell region CR.

A buffer pattern 210, an intervening pattern 310, a bit line contact DC, a buried insulating pattern 250, a bit line spacer 360, a storage node contact BC, and a capping spacer 370 may be formed. Storage node contacts BC and fence patterns FN may be formed between neighboring bit lines BL.

A second barrier pattern 410 may be formed to cover the bit line capping pattern 350. The second barrier pattern 410 may be formed to conformally cover the bit line spacer 360, the storage node contact BC, and the capping spacer 370. An upper surface of the second barrier pattern 410 may be exposed. The first trench TR1 in FIG. 2 may correspond to a landing trench LTR formed by the second barrier pattern 410.

Forming the landing pad LP may include forming a landing trench LTR on the storage node contact BC, forming a landing pad layer eLP on the landing trench LTR, sequentially forming mask patterns (not shown) on the landing pad layer eLP, separating the landing pad layer eLP into a plurality of landing pads LP through anisotropic etching using the mask patterns as an etch mask.

Referring again to FIG. 12A, the forming of the landing pad LP will be described in more detail. The landing pad layer eLP may be formed on the landing trench LTR. The landing pad layer eLP may include completely or partially filling the landing trench LTR with, for example, the first compound M1 of FIGS. 1 to 6.

Referring to FIGS. 12B and FIGS. 2 to 6, forming the landing pad LP may include (a) forming the landing trench LTR on the storage node contacts BC, (b) adsorbing first particles P1 and second particles P2 along an inner wall of the landing trench LTR to form a first layer L1, (c) flowing an inert gas on the first layer L1, (d) flowing the third particles P3 on the first layer L1 to form the first compound M1 included in the landing pad layer eLP, and (e) forming a filler in the landing trench LTR based on the first compound M1 to form the landing pad layer eLP.

In this case, the characteristics of the manufacturing method for forming the landing pad layer eLP are the same as those described above in FIGS. 1 to 6.

Referring to FIG. 12B, the landing pad layer eLP may be separated into a plurality of landing pads LP through an etching process. Through the etching process, a portion of the second barrier pattern 410, a portion of the bit line spacer 360, and a portion of the bit line capping pattern 350 may be further etched and exposed to the outside. The upper portion of the landing pad LP may be shifted from the storage node contact BC in the second direction D2. As an example, the landing pad LP may include a metal material (e.g., tungsten, titanium, tantalum, etc.).

Referring to FIG. 12C, a filling pattern 440 may be formed to cover the exposed portions and surround each of the landing pads LP, and a data storage pattern DSP may be formed on each of the landing pads LP.

The data storage pattern DSP may be formed on each of the landing pads LP.

The data storage pattern DSP may be, for example, a capacitor including a lower electrode, a dielectric layer, and an upper electrode. In this case, the semiconductor memory device according to the inventive concept may be a dynamic random access memory (DRAM). As another example, the data storage pattern DSP may include a magnetic tunnel junction pattern. In this case, the semiconductor memory device according to the inventive concept may be a magnetic random access memory (MRAM). As another example, the data storage pattern DSP may include a phase change material or a variable resistance material. In this case, the semiconductor memory device according to the inventive concept may be a phase-change random access memory (PRAM) or a resistive random access memory (ReRAM). However, this is only an example and the inventive concept is not limited thereto, and the data storage pattern DSP May include various structures and/or materials capable of storing data.

According to the inventive concept, after forming the first trench, when forming a filler in the first trench based on the first compound, the reaction rate at which the first compound is formed is different depending on the distance from the lower surface of the first trench, so that the first trench may be filled sequentially from the bottom to the top. Accordingly, the manufacturing defects may be reduced.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A method of manufacturing a semiconductor device, the method comprising:
(a) forming a first trench;
(b) adsorbing first particles from a first gas, the first particles comprising a first material and second particles from a second gas, the second particles comprising a second material different from the first material along an inner wall of the first trench to form a first layer;
(c) flowing an inert gas onto the first layer;
(d) adsorbing third particles on the first layer to form a first compound; and
(e) at least partially filling the first trench with the first compound to form a filler,
wherein step (b) includes:
increasing an abundance of the first gas as a distance from a lower surface of the first trench increases, wherein the abundance comprises a partial pressure or a density of the first gas; and
making an abundance of the second gas substantially constant regardless of the distance from the lower surface of the first trench, wherein the abundance comprises a partial pressure or a density of the second gas.

2. The method of claim 1, wherein the first particles include TiCl₄, and
wherein the second particles include dichlorosilane (DCS) or SiH₄.

3. The method of claim 1, wherein step (b) includes:
flowing an unsaturated amount of the first particles along the inner wall of the first trench, and
flowing a sufficient amount of the second particles to saturate onto the first particles adsorbed along the inner wall of the first trench.

4. The method of claim 1, wherein the third particles include NH₃, and
wherein the first compound includes titanium silicon nitride.

5. The method of claim 1, wherein step (b) includes:
flowing an amount of the first gas insufficient to saturate the first particles along the inner wall and an amount of the second gas sufficient to saturate the second particles, wherein the first particles and the second particles are admixed together along the inner wall of the first trench.

6. The method of claim 1, wherein step (b) is performed at a temperature of 500° C. or more and less than 650° C.

7. The method of claim 1, wherein step (d) includes reacting the first layer and the third particles, and
wherein a reaction rate of the reaction decreases as the distance from the lower surface of the first trench increases.

8. The method of claim 1, further comprising, after step (e), forming a data storage pattern on the filler.

9. A method of manufacturing a semiconductor device, the method comprising:
(a) forming a first trench on a base substrate;
(b) adsorbing first particles of a first material and second particles of a second material different from the first material along an inner wall of the first trench to form a first layer;
(c) flowing an inert gas onto the first layer;
(d) flowing third particles on the first layer to form a first compound; and
(e) at least partially filling the first trench with the first compound to form a filler,
wherein step (d) includes reacting the first layer and the third particles, and
wherein a reaction rate between the first layer and the third particles decreases as a distance from a lower surface of the first trench increases.

10. The method of claim 9, wherein a density of the adsorbed first particles of the first layer increases as the distance from the lower surface of the first trench increases.

11. The method of claim 9, wherein in step (b):
the first particles are adsorbed from a first gas comprising the first material; and
the second particles are adsorbed from a second gas comprising the second material; and
wherein step (b) includes:
increasing a partial pressure of the first gas as the distance from the lower surface of the first trench increases, and
making a partial pressure of the second gas substantially constant regardless of the distance from the lower surface of the first trench.

12. The method of claim 9, wherein the first material includes TiCl₄,
wherein the second material includes dichlorosilane (DCS) or SiH₄, and
wherein the third particles include NH₃.

13. The method of claim 9, wherein step (a) includes etching the base substrate using mask patterns as an etch mask, and
wherein step (e) includes forming the filler in the first trench based on the first compound from the lower surface of the first trench without gaps.

14. The method of claim 9, wherein step (b) is performed at a temperature at which the first particles and the second particles do not react with each other.

15. The method of claim 9, wherein step (a) includes forming the first trench to penetrate a portion of the base substrate including a cell active region, and
wherein the first trench exposes a portion of a word line on the cell active region.

16. The method of claim 9, wherein step (e) includes:
(f) adsorbing additional first particles of the first material and additional second particles of the second material into the first trench partially filled with the first compound;
(g) flowing the third particles onto the adsorbed first particles, and the adsorbed second particles;
(h) flowing the inert gas; and
repeating steps (f) to (h) until the first trench is fully filled with the first compound.

17. The method of claim 9, wherein the first compound includes silicon-doped titanium nitride, and
wherein a silicon doping concentration of the first compound increases as a surface thereof approaches the lower surface of the first trench.

18. A method of manufacturing a semiconductor device, the method comprising:
providing a substrate including cell regions;
forming word lines on the cell region and bit lines electrically connected to the word lines;
forming storage node contacts and fence patterns between neighboring bit lines; and
forming landing pads on the storage node contacts,
wherein the forming of the landing pads includes:
(a) forming a landing trench on the storage node contacts;
(b) adsorbing first particles of a first material and second particles of a second material different from the first material along an inner wall of the landing trench to form a first layer;
(c) flowing an inert gas onto the first layer;
(d) flowing third particles on the first layer to form a first compound; and
(e) at least partially filling the landing trench with the first compound to form a filler,
wherein step (d) includes reacting the first layer and the third particles, and
wherein a reaction rate between the first layer and the third particles decreases as a distance from a lower surface of the landing trench increases.

19. The method of claim 18, wherein the first material includes TiCl₄,
wherein the second material includes dichlorosilane (DCS) or SiH₄, and
wherein the third particles include NH₃.

20. The method of claim 19, wherein the first compound includes silicon-doped titanium nitride, and
wherein a silicon doping concentration of the first compound increases as a surface thereof approaches the lower surface of the landing trench.
